(19) United States
(12) Patent Application Publication
(10) Pub. No.: US 2006/0279335 A1
(43) Pub. Date: Dec. 14, 2006

(54) Phase interpolator driver

(75) Inventor: Noam Familia, Modiin (IL)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/125,537

(22) Filed: May 9, 2005

(51) Int. Cl. H03K 19/094

(52) U.S. Cl. 326/83

(57) ABSTRACT

A driver circuit in a phase interpolator is provided. In some embodiments, it comprises an input to receive an input clock signal, an output; and at least one pull-up and pull-down device coupled between the input and output to provide at the output the input clock signal driven at a desired level. The at least one pull-up and pull-down devices comprise a plurality of selectably engageable devices to drive the input clock signal at the desired level. Other embodiments are described and/or claimed herein.

### BACKGROUND

Phase interpolators are commonly used to generate desire clock phases off of input, reference clock signals. They may be used in various applications such as with phase locked loops (PLLs), delay locked loops (DLLs), and clock data recovery (CDR) circuits. With CDR circuits, for example, they may be used in data recovery by a receiver to locate data edges and find an appropriate sampling point. In such applications, a strobe may be swept through a data period using small steps until a suitable point is found. When the resolution of these steps is higher, the system is generally able to recover data for narrower valid windows. In order to achieve better resolutions, DLLs or PLLs with phase interpolators may be used.

With reference to FIG. 1, a conventional phase interpolator 100 is shown. It generally includes first and second drivers 103, 105, which receive out-of-phase input clock signals 102, 104 (CLK A, CLK B) respectively. The driver outputs are coupled to one another to generate an output signal (CLK C) whose phase is an interpolation between the two input clock signal phases. The actual interpolation location is a function of the ratio between the strength of driver A to driver B. It will proportionally be closer to the clock that is input to the strongest driver.

Typically, each driver 103, 105 has a number of discrete strength options to achieve the different, desired interpolation intervals between the input clock phases. The resolution of the phase interpolator is normally dependent on the number of strength settings. With phase interpolator 100, each driver 103, 105 has five (N=0, 1, 2, 3, or 4) different strength settings resulting in five different phase interpolation settings, as indicated at 106. The relative strength of driver A (103) is N, and the strength of driver B (105) is 4−N. Thus, as illustrated at 106, as N gets larger, the output phase moves toward CLK A. Likewise, as it gets smaller, it moves closer to CLK B.

FIG. 2 shows a conventional driver circuit 200 commonly used as a driver in the phase interpolator 100 of FIG. 1. The driver comprises pull-up resistors R1, R2, pull-down NMOS transistors M1, M2, and a number of selectably engageable current source NMOS transistors M_{N}REF. (The term “NMOS transistor” refers to an N-type metal oxide semiconductor field effect transistor. Likewise, “PMOS transistor” refers to a P-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. Other suitable transistor types, e.g., junction-field-effect, bipolar-junction-transistor, known today or not yet developed, could be used in their place.)

The driver circuit has a differential clock signal input (CLK, CLK#) at the gates of M1 and M2, and a differential output (OUT#/OUT) at the junction nodes between the pull-up resistors R1, R2 and the pull-down transistors M1, M2, respectively. The different current source transistors M_{N}REF are engaged or disengaged by way of a control signal (CTL). The higher the number of engaged current sources, the stronger the driving strength of the driver 100. For example, if driver circuit 200 is used as the drivers for driver A and driver B in FIG. 1, with a CTL selection of N=3, three current source transistors M_{N}REF would be engaged for driver A with one current source transistor M_{N}REF being engaged for driver B.

Linearity may be an important parameter in some phase interpolator applications. For example, it can affect accuracy, as well as resolution. As the linearity of a phase interpolator gets better, the worst case step in the phase interpolator can be made to be smaller. The smaller the worst case step, the higher the achievable resolution of the output clock interpolation. Unfortunately, in some applications, with conventional driver circuits, the interpolation transitions may not be suitably linear.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram of a prior art phase interpolator.

FIG. 2 is a schematic diagram of a prior art driver circuit for a phase interpolator such as the phase interpolator of FIG. 1.

FIG. 3 is a schematic diagram of a driver circuit suitable for the phase interpolator of FIG. 1 according to some embodiments of the present invention.

FIG. 4 is a block diagram of a computer system with at least one phase interpolator in accordance with some embodiments of the present invention.

### DETAILED DESCRIPTION

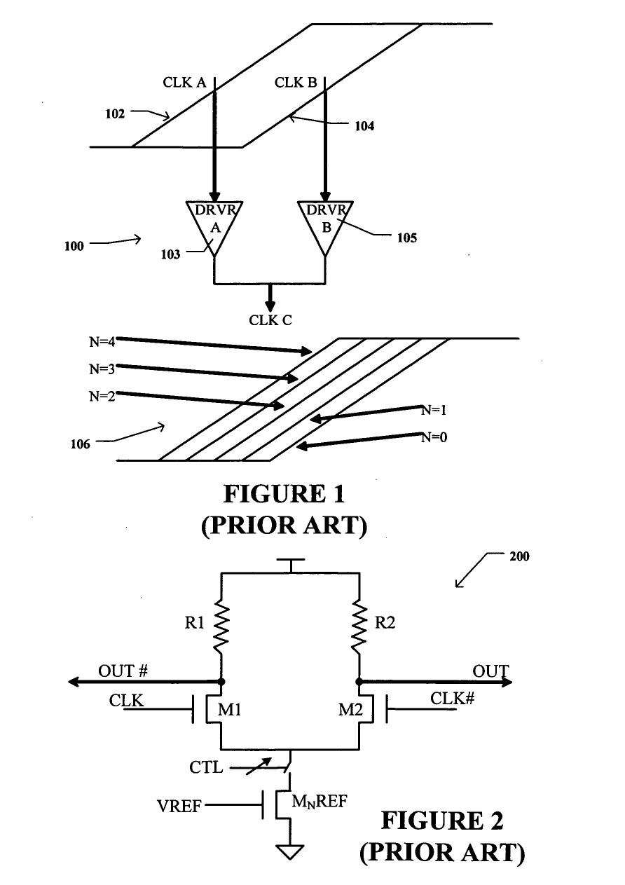

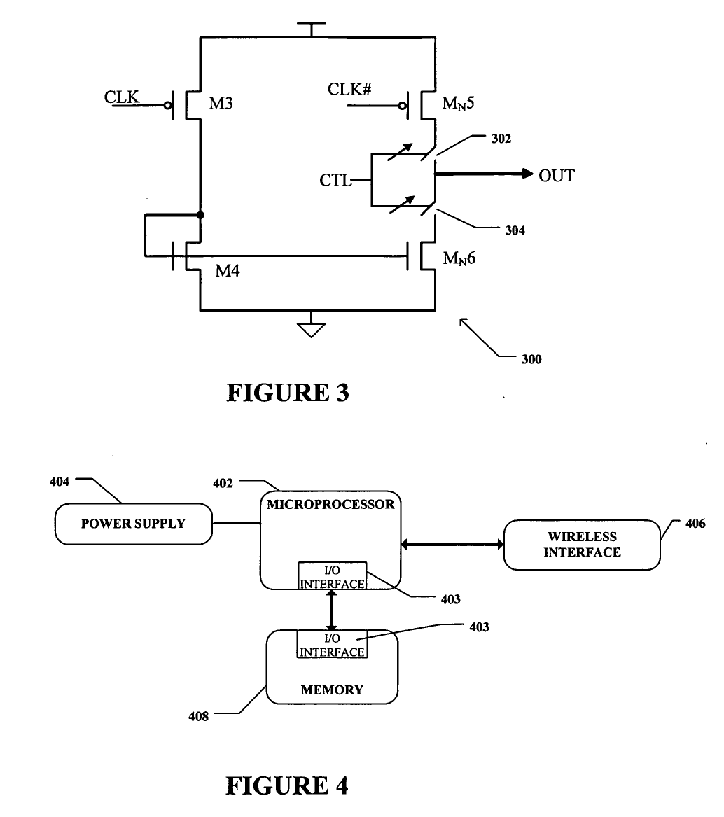

FIG. 3 shows a driver circuit 300 for a phase interpolator. In some embodiments, it may be used for drivers A and B in the phase interpolator of FIG. 1. The circuit generally comprises a first leg formed from pull-up transistor M3, coupled to pull-down transistor M4 and a second leg formed from a plurality of selectably engageable pull-up/pull-down transistor pairs M_{N}5/M_{N}6. Transistors M_{N}5 and M_{N}6 are selectably coupled (or engageable) within the circuit through switches (e.g., suitably conductive transistors) 302 and 304. The first and second legs are coupled between V_{cc} and ground, although they could be coupled between any suitable reference nodes. The driver circuit comprises a differential input (CLK/CLK#) at the gates of M3 and M_{N}5, respectively, and a single-ended output (OUT) at a junction node between pull-up transistors M_{N}5 and pull-down transistors M_{N}6. In particular, in the depicted figure, it is at a node between switches 302 and 304. (for the phase interpolator topology of FIG. 1, the single-ended outputs may be coupled to one another just as the differential outputs for the circuit of FIG. 2 are coupled together, except that a single line instead of dual lines may be used.)

Pull-down transistors M4 and MN6 are coupled to one another in a current-mirror configuration, thereby making the current in the second leg proportional to the current in the first leg. The actual value will correspond to the number of pull-up/pull-down pairs M_{N}5/M_{N}6 that are engaged. That is, the current (and thus the driving strength of the driver circuit 300) increases as the number of engaged pull-up/pull-down transistor pairs increases. In one embodiment, four selectably engageable pairs M^{N}5/M^{N}6, are utilized. One or more of them can be enabled using a control signal (CTL), which controls the opening/closing of switches 302, 304 to selectably engage (or disengage) a selected number of the pull-up/pull-down pairs. (Note that the CTL signal may actually comprise several different signals, e.g., one for each pull-up/pull-down pair.)

The selectably engageable pull-up/pull-down pairs may provide good, linear interpolation because, among other reasons, they can be configured to have substantially equivalent operating characteristics (e.g. equivalent conductance/current). Thus, by adding or removing them from the driver, one can vary the driving strength of the driver by equivalent (or reasonably equivalent) linear increments. to achieve this, the transistors (or at least suitable combinations of them) can be matched (e.g., sized) and biased to operate reasonably equivalently with one another. For example, in one embodiment, dual, parallel-connected transistors—each having a channel length of 1μ and a width of 0.1μ—may be used for each depicted transistor M3, M4, M_{N}5, and M_{N}6. (Dual, parallel-connected 1μ transistors are essentially equivalent to a 2μ transistor. Two parallel-connected devices, instead of a single, wider device, can be used for better matching, i.e., increased fabrication precision and consistency.) Even if all of the devices are not reasonably matched with one another, the pull-up transistors M3, M_{N}5 may be matched to one another, and the pull-down transistors M4, MN6 may be matched to one another. In addition, the corresponding devices in each driver used to implement a phase interpolator, e.g., a phase interpolator such as that shown in FIG. 1 but with the drivers of FIG. 3, may also have suitably matched characteristics.

In the depicted embodiment, the pull-up and pull-down transistors are implemented with PMOS and NMOS transistors, respectively. However, any suitable transistor types or circuit components (e.g., resistors, rectifiers) or combinations thereof could otherwise be used. Similarly, the depicted embodiment employs a single-ended output (OUT). However, other output types such as differential outputs could also be implemented. For example, with the depicted circuit, an equivalent circuit but with the clock input polarities switched, could be used to generate a complementary output that when coupled with the depicted output could provide a differential output. Along these lines, while the depicted clock input signal is fed into the gates of the pull-up PFET transistors M3, MN5, this is not required. For example, they instead could be fed into the pull-down NFETs, with the pull-up PFETs, for example, possibly connected in the current-mirror configuration. (Note that the current mirror configuration is not necessary but may provide better results in some applications.)

With reference to FIG. 4, one example of a computer system is shown. The depicted system generally comprises a processor 402 that is coupled to a power supply 404, a wireless interface 406, and memory 408. It is coupled to the power supply 404 to receive from it power when in operation. It is coupled to the wireless interface 406 and to the memory 408 with separate point-to-point links to communicate with the respective components. It, along with memory component 408, includes an I/O interface 403, which includes a phase interpolator with drivers configured in accordance with a driver as discussed with reference to FIG. 3. For example, in some embodiments, the memory may be a DDR memory component, and the phase interpolator could be used in a clock data recovery application in a receiver in the I/O interfaces 403.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A circuit, comprising:
a driver circuit in a phase interpolator, the driver circuit comprising:
an input to receive an input clock signal;
an output; and
at least one pull-up and pull-down transistor coupled between the input and output to provide at the output the input clock signal driven at a desired level, the at least one pull-up and pull-down transistors comprising a plurality of selectably engageable transistors to drive the input clock signal at the desired level.

2. The circuit of claim 1, in which the at least one pull-up and pull-down transistors are coupled between first and second supply reference nodes.

3. The circuit of claim 2, in which the first supply reference node is a supply voltage node and the second supply reference node is a ground node.

4. The circuit of claim 1, in which the input comprises a differential clock input.

5. The circuit of claim 4, in which the at least one pull-up and pull-down transistors comprise first and second legs each comprising at least one pull-up and pull-down transistor coupled to one another, said pull-up and pull-down transistors in the second leg being coupled to one another at a common node defining the driver output.

6. The circuit of claim 5, in which the second leg comprises a plurality of selectably engageable pull-up and pull-down transistors to drive the input clock signal at the desired level.

7. The circuit of claim 6, in which the pull-up transistors comprise PMOS transistors having gates with the driver input being at their gates.

8. The circuit of claim 7, in which the pull-down transistors in the second leg, when engaged, are coupled to the pull-down transistor in the first leg in a current-mirror configuration.

9. A phase interpolator having first and second drivers in accordance with the driver of claim 1, said first and second drivers being coupled to one another at their outputs to define an output of the phase interpolator.

10. A chip comprising:
a phase interpolator having first and second drivers each comprising
an input to receive an input clock signal;
an output; and
at least one pull-up and pull-down transistor coupled between the input and output to provide at the output the input clock signal driven at a desired level, the at least one pull-up and pull-down transistors comprising a plurality of selectably engageable transistors to drive the input clock signal at the desired level, the phase interpolator having an output formed from the outputs of the first and second drivers coupled to one another.

11. The chip of claim 10, in which the at least one pull-up and pull-down transistors in each driver are coupled between first and second supply reference nodes.

12. The chip of claim 11, in which the first supply reference node is a supply voltage node and the second supply reference node is a ground node.

13. The chip of claim 10, in which the driver inputs are differential clock inputs.

14. The chip of claim 13, in which the at least one pull-up and pull-down transistors in each driver comprise first and second legs each comprising at least one pull-up and pull-down transistor coupled to one another, said pull-up and pull-down transistors in the second leg being coupled to one another at a common node defining the driver output.

15. The chip of claim 5, in which the second leg comprises a plurality of selectably engageable pull-up and pull-down transistors to drive the input clock signal at the desired level.

16. The chip of claim 15, in which the pull-up transistors comprise PMOS transistors having gates with the driver input being at their gates.

17. The chip of claim 16, in which the pull-down transistors in the second leg, when engaged, are coupled to the pull-down transistor in the first leg in a current-mirror configuration.

18. A system, comprising:
(a) a microprocessor having an I/O interface with a phase interpolator comprising: a driver circuit in the phase interpolator, the driver circuit comprising:
an input to receive an input clock signal;
an output; and
at least one pull-up and pull-down transistor coupled between the input and output to provide at the output the input clock signal driven at a desired level, the at least one pull-up and pull-down transistors comprising a plurality of selectably engageable transistors to drive the input clock signal at the desired level; and
(b) a power supply coupled to the microprocessor to supply it with power.

19. The system of claim 18, in which the power supply comprises a battery.

20. A circuit, comprising:
a driver circuit in a phase interpolator, the driver circuit comprising:
an input to receive an input clock signal;
an output; and
at least one pull-up and pull-down device coupled between the input and output to provide at the output the input clock signal driven at a desired level, the at least one pull-up and pull-down devices comprising a plurality of selectably engageable devices to drive the input clock signal at the desired level.

21. The circuit of claim 20, in which the at least one pull-up and pull-down devices are transistors.

22. The circuit of claim 21, in which the at least one pull-up and pull-down devices comprise transistors and resistors.
